(19) United States
(12) Patent Application Publication
(10) Pub. No.: US 2026/0020253 A1
(43) Pub. Date: Jan. 15, 2026

(54) SEMICONDUCTOR DEVICE

(71) Applicant: Samsung Electronics Co., Ltd., Suwon-si (KR)

(72) Inventors: Hyunjung Lee, Suwon-si (KR); Taemin Cha, Suwon-si (KR); Jinyeol Lee, Suwon-si (KR); Yootak Jun, Suwon-si (KR)

(21) Appl. No.: 19/091,091

(22) Filed: Mar. 26, 2025

(30) Foreign Application Priority Data
Jul. 15, 2024 (KR) 10-2024-0093249

(51) Int. Cl. H10B 80/00; H01L 23/00; H01L 25/065; H01L 25/18; H10B 12/00

(52) U.S. Cl. CPC H10B 80/00; H01L 24/08; H01L 25/0657; H01L 25/18; H10B 12/315; H01L 2224/08145; H01L 2924/1431; H01L 2924/1436

(57) ABSTRACT

A semiconductor device includes a first semiconductor structure having a memory region, and a second semiconductor structure vertically overlapping the first semiconductor structure, the second semiconductor structure having a peripheral circuit region vertically overlapping the memory region. The first semiconductor structure includes a memory structure including a vertical channel transistor disposed in the memory region and an information storage structure disposed on the vertical channel transistor, and a cell routing line structure electrically connected to the memory structure. The second semiconductor structure includes a peripheral circuit disposed in the peripheral circuit region, and a peripheral routing line structure electrically connecting the peripheral circuit and the cell routing line structure to each other. The first semiconductor structure further includes a cell hydrogen supply layer disposed between the memory structure and the second semiconductor structure.

### CROSS-REFERENCE TO RELATED APPLICATION(S)

This application claims benefit of priority to Korean Patent Application No. 10-2024-0093249 filed on Jul. 15, 2024, in the Korean Intellectual Property Office, the disclosure of which is incorporated herein by reference in its entirety.

### BACKGROUND

The present inventive concept relates to a semiconductor device. Specifically, the present disclosure relates to hydrogen annealing for improving electrical properties of a transistor.

As demand for implementation of high performance, high speed, and/or multifunctionalization of semiconductor devices increases, a degree of integration of semiconductor devices has been increasing. As semiconductor devices are integrated, a hydrogen treatment may be performed to secure a refresh time of a DRAM cell transistor. The hydrogen treatment may be performed to improve electrical connection properties between metal lines or between a semiconductor substrate and a metal line, and to improve properties of semiconductor devices.

### SUMMARY

An aspect of the present inventive concept provides a semiconductor device having improved electrical properties.

However, the aspects of the present inventive concept are not limited to the aspects set forth herein, and may be extended in various manners without departing from the spirit and area of the present inventive concept.

According to an aspect of the present inventive concept, there is provided a semiconductor device including a first semiconductor structure having a memory region, and a second semiconductor structure vertically overlapping the first semiconductor structure, the second semiconductor structure having a peripheral circuit region vertically overlapping the memory region. The first semiconductor structure may include a memory structure including a vertical channel transistor disposed in the memory region and an information storage structure disposed on the vertical channel transistor, and a cell routing line structure electrically connected to the memory structure. The second semiconductor structure may include a peripheral circuit disposed in the peripheral circuit region, and a peripheral routing line structure electrically connecting the peripheral circuit and the cell routing line structure to each other. The first semiconductor structure may further include a cell hydrogen supply layer disposed between the memory structure and the semiconductor second structure.

According to another aspect of the present inventive concept, there is provided a semiconductor device including a first semiconductor structure having a memory region, and a second semiconductor structure, in contact with the first semiconductor structure, the second semiconductor structure having a peripheral circuit region vertically overlapping the memory region. The first semiconductor structure may include a memory structure including a vertical channel transistor disposed in the memory region, and an information storage structure disposed on the vertical channel transistor, a cell routing line structure disposed below the vertical channel transistor, the cell routing line structure electrically connected to the memory structure, a cell bonding structure disposed below the cell routing line structure, a cell hydrogen supply layer, surrounding a portion of the cell routing line structure, between the cell bonding structure and the vertical channel transistor, the cell hydrogen supply layer including a first insulating material, and a cell insulating layer, surrounding at least a portion of the vertical channel transistor, on the cell hydrogen supply layer, the cell insulating layer including a second insulating material, different from the first insulating material. The second semiconductor structure may include peripheral circuits disposed in the peripheral circuit region, a peripheral routing line structure electrically connecting the peripheral circuits and the cell routing line structure to each other, and a peripheral bonding structure disposed on the peripheral routing line structure, the peripheral bonding structure in contact with the cell bonding structure.

According to another aspect of the present inventive concept, there is provided a semiconductor device including a first semiconductor structure having a memory region, and a second semiconductor structure, in contact with the first semiconductor structure, the second semiconductor structure vertically overlapping the first semiconductor structure, the second semiconductor structure having a peripheral circuit region vertically overlapping the memory region. The first semiconductor structure may include a memory structure including a vertical channel transistor disposed in the memory region, and an information storage structure disposed on the vertical channel transistor, and a cell routing line structure electrically connected to the memory structure. The second semiconductor structure may include a peripheral circuit disposed in the peripheral circuit region, and a peripheral routing line structure electrically connecting the peripheral circuit and the cell routing line structure to each other. The first semiconductor structure may further include a cell hydrogen supply layer, surrounding a portion of the cell routing line structure, between the vertical channel transistor and the second structure. The second semiconductor structure may further include a peripheral hydrogen supply layer surrounding a portion of the peripheral routing line structure.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a schematic perspective view of a semiconductor device according to example embodiments of the present inventive concept;

FIG. 1B is a circuit layout diagram of a memory structure in a memory region of the semiconductor device of FIG. 1A according to an example embodiment.

FIG. 2 is a schematic plan view of a memory region of the semiconductor device of FIG. 1A;

FIG. 3 is cross-sectional views of a semiconductor device as illustrated in FIG. 2 according to an example embodiment, taken along line I-I′ and line II-II′;

FIGS. 4A to 4C are cross-sectional views of a semiconductor device as illustrated in FIG. 2 according to another example embodiment, taken along line I-I′ and line II-II′; and

FIGS. 5A to 5C are cross-sectional views of a semiconductor device as illustrated in FIG. 2 according to another example embodiment, taken along line I-I′ and line II-II′.

### DETAILED DESCRIPTION

Hereinafter, the present disclosure will be described more fully with reference to the accompanying drawings, in which various embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail. The language of the claims should be referenced in determining the requirements of the invention.

In the disclosure, the same reference numerals are used for the same components in the drawings, and repeated descriptions of the same components may be omitted. Items described in the singular herein may be provided in plural, as can be seen, for example, in the drawings. Thus, the description of a single item that is provided in plural should be understood to be applicable to the remaining plurality of items unless context indicates otherwise.

As used herein, a semiconductor device may refer to any of the various devices such as shown in the figures, and may also refer, for example, to two transistors or a device such as a semiconductor chip (e.g., memory chip and/or logic chip formed on a die), a stack of semiconductor chips, a semiconductor package including one or more semiconductor chips stacked on a package substrate, or a package-on-package device including a plurality of packages. These devices may be formed using ball grid arrays, wire bonding, through substrate vias, or other electrical connection elements, and may include memory devices such as volatile or non-volatile memory devices.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred). Moreover, components that are “directly electrically connected” form a common electrical node through electrical connections by one or more conductors, such as, for example, wires, pads, internal electrical lines, through vias, etc. As such, directly electrically connected components do not include components electrically connected through active elements, such as transistors or diodes.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first”) in a particular claim may be described elsewhere with a different ordinal number (e.g., “second”) in the specification or another claim.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

An item, layer, or portion of an item or layer described as extending “lengthwise” in a particular direction has a length in the particular direction and a width perpendicular to that direction, where the length is greater than the width.

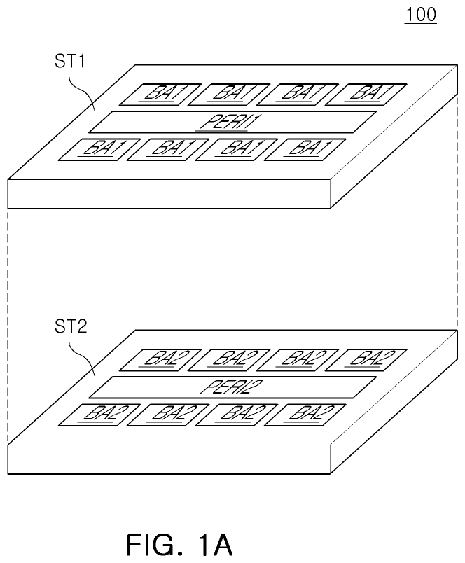

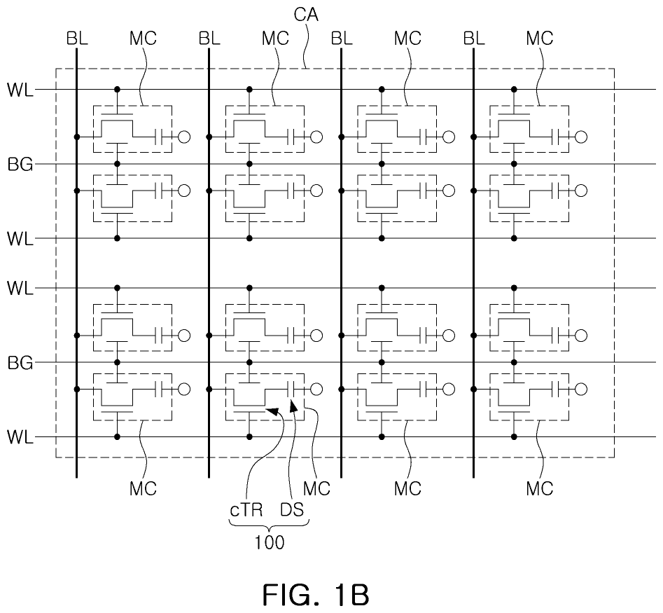

FIG. 1A is a schematic perspective view of a semiconductor device according to example embodiments of the present inventive concept. FIG. 1B is a circuit diagram of a memory structure in a memory region of the semiconductor device of FIG. 1A according to an example embodiment.

Referring to FIGS. 1A and 1B, a semiconductor device 100 may include a first structure ST1 (e.g., a first semiconductor chip) and a second structure ST2 (e.g., a second semiconductor chip) vertically overlapping the first structure ST1. The first structure ST1 may be disposed on the second structure ST2. However, the present inventive concept is not limited thereto, and the first structure ST1 may be disposed below the second structure ST2.

The first structure ST1 may be a first chip structure including memory cells, and the second structure ST2 may be a second chip structure including a peripheral circuit that may implement the operation of the memory cells. In an example, the first structure ST1 and the second structure ST2 may be bonded to each other using a bonding process such as a wafer bonding process. The first structure ST1 may be bonded to the second structure ST2 while being in contact with the second structure ST2.

The semiconductor device 100 may include a plurality of banks and a plurality of peripheral regions (e.g., a first peripheral region PERI1 and a second peripheral region PERI2).

The plurality of peripheral regions may include a first peripheral region PERI1 in the first structure ST1, and a second peripheral region PERI2 in the second structure ST2. The first and second peripheral regions PERI1 and PERI2 may be peripheral circuit regions in which peripheral circuits for input/output of data or a command or input of power/ground are disposed.

Each bank of the plurality of banks may include a first bank region BA1 in the first structure ST1 and a second bank region BA2 in the second structure ST2.

Each first bank region BA1 in the first structure ST1 may include a corresponding memory region CA.

Each second bank region BA2 in the second structure ST2 may include a corresponding peripheral circuit region. The peripheral circuit regions of the second bank regions BA2 may overlap respective memory regions CA of the first bank regions BA1, in a vertical direction (Z-direction). Each of the peripheral circuit regions may include a sense amplifier region and a sub word line driver region.

Each memory region CA may include memory cells MC. Each memory region CA may include memory cells MC arranged in a first direction (X-direction) and a second direction (Y-direction), word lines WL extending lengthwise in the first direction (X-direction) and connected to the memory cells MC, and bit lines BL extending lengthwise in the second direction (Y-direction) and connected to the memory cells MC.

Each of the memory cells MC may include a cell transistor cTR, serving as a switch, and an information storage structure DS, serving as information storage. In a memory such as a DRAM, the information storage structure DS may be a cell capacitor that stores a charge representative of stored information.

Each of the memory regions CA may further include back gate lines BG. Each of the back gate lines BG may be disposed between a pair of word lines WL that are adjacent to each other in the second direction (Y-direction) from among the word lines WL of the memory region CA. Each of the back gate lines BG may be disposed between channel regions of the cell transistors cTR.

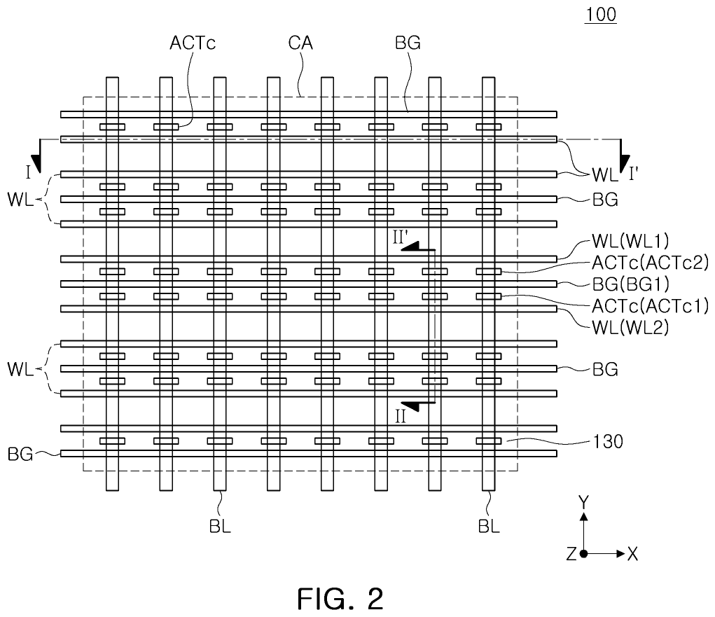

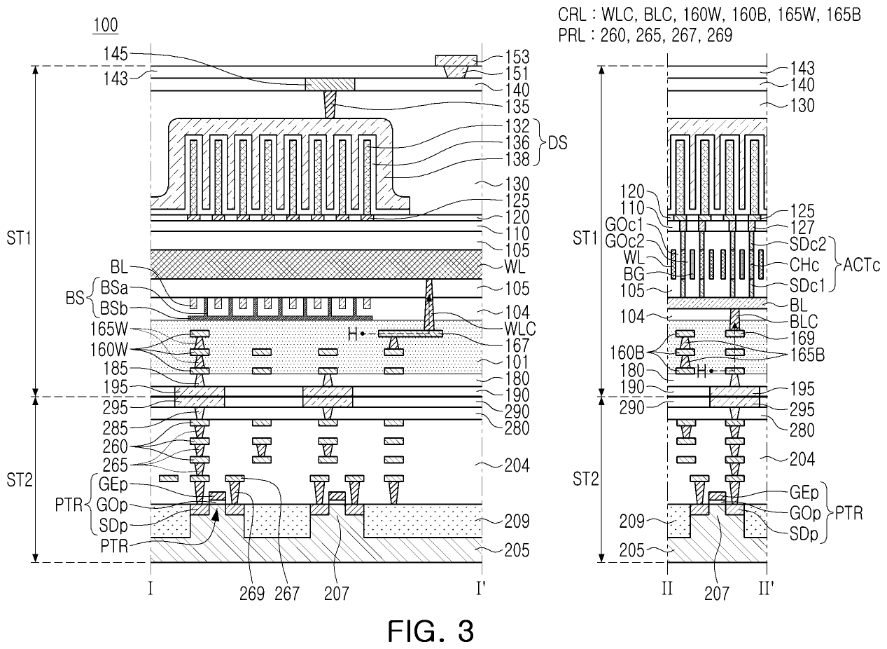

FIG. 2 is a schematic plan view of a memory region of the semiconductor device of FIG. 1A. FIG. 3 is cross-sectional views of the semiconductor device illustrated in FIG. 2 according to an example embodiment, taken along line I-I′ and line II-II′.

Referring to FIGS. 2 and 3 together with FIGS. 1A and 1B, the semiconductor device 100 may include a first structure ST1 (e.g., a first semiconductor structure) and a second structure ST2 (e.g., a second semiconductor structure) in contact with the first structure ST1. In an example, the first structure ST1 may include cell transistors cTR in the memory region CA, information storage structures DS, and a cell routing line structures CRL electrically connected to the cell transistors cTR and the information storage structures DS. The second structure ST2 may include peripheral transistors PTR and peripheral routing line structures PRL, connected to the peripheral transistors PTR, in the peripheral circuit region.

The cell transistor cTR may include a word line WL extending lengthwise in the first direction (X-direction), a bit line BL extending lengthwise in the second direction (Y-direction), back gate lines BG extending lengthwise in the first direction (X-direction), and active patterns ACTc.

The active patterns ACTc may include a semiconductor material that may be used as a channel of a transistor. For example, the active patterns ACTc may include at least one of a silicon layer, an oxide semiconductor layer, or a two-dimensional material layer having semiconductor properties. For example, each of the active patterns ACTc may include single crystal silicon or polysilicon. The active patterns ACTc may be arranged in the first direction (X-direction) and the second direction (Y-direction). The active patterns ACTc may have a bar shape extending (e.g., extending lengthwise) in the first direction (X-direction).

Each of the active patterns ACTc may include a first source/drain region SDc1, a second source/drain region SDc2 disposed at a level higher than that of the first source/drain region SDc1, and a cell channel region CHc between the first and second source/drain regions SDc1 and SDc2.

Each of the cell transistors cTR may further include a cell gate dielectric layer GOc1 in contact with a first side surface of the cell channel region CHc and a side surface of the word line WL. A portion of the word line WL, facing the cell channel region CHc, may be a gate electrode. Each of the word lines WL may have a vertical length greater than a width in the second direction (Y direction). The vertical length of the word line WL may be a length from a lower surface to an upper surface of the word line WL. The word lines WL may have side surfaces, facing side surfaces of the active patterns ACTc.

In a plane as illustrated in FIG. 2, the word lines WLs may include a first word line WL1 and a second word line WL2, adjacent to each other in a second direction (Y-direction) (e.g., spaced apart in the second direction but with no intervening word lines between the first word line WL1 and the second word line WL2), and the active patterns ACTc may include a first active pattern ACTc1 adjacent to the first word line WL1 and a second active pattern ACTc2 adjacent to the second word line WL2, with the first active pattern ACTc1 and the second active pattern ACTc2 both between the first and second word lines WL1 and WL2. Each of the back gate lines BG may be disposed between adjacent word lines WL (e.g., a back gate line BG is disposed between the first and second word lines WL1 and WL2), and the back gate lines may include a first back gate line BG1 passing through a space between the first active pattern ACTc1 and the second active pattern ACTc2. The back gate lines BG may be back gate electrodes.

Each of the cell transistors cTR may further include a back gate dielectric layer GOc2 between a back gate line BG and the active patterns ACTc. Each of the back gate lines BG may have side surfaces, facing side surfaces of the cell channel regions CHc of the active patterns ACTc adjacent to the back gate line BG. Each of the active patterns ACTc may be disposed between one word line WL and one back gate line BG that are adjacent to each other and separated by a respective active pattern ACTc.

The back gate lines BG may control charges accumulated in the cell channel regions CHc. The cell channel regions CHc may be a floating body disposed between the first and second source/drain regions SDc1 and SDc2, and the back gate lines BG may suppress or prevent performance of the cell transistor cTR from being degraded due to a floating body effect, and may improve performance of the cell transistor cTR. For example, during an operation of the cell transistor cTR, charges (e.g., holes) may be accumulated in the floating body of the cell channel region CHc to minimize or prevent a threshold voltage of the cell transistor cTR from varying.

The word lines WL may be formed of doped polysilicon, Al, Cu, Ti, Ta, Ru, W, Mo, Pt, Ni, Co, TiN, TaN, WN, NbN, TiAl, TiAlN, TiSi, TiSiN, TaSiN, TaSiN, RuTiN, NiSi, CoSi, or combinations thereof, but the present inventive concept is not limited thereto. Each of the word lines WL may include a single layer or multiple layers, formed of the above-described conductive materials. The back gate lines BG may include at least one conductive material. For example, each of the back gate lines BG may be formed of doped polysilicon, Al, Cu, Ti, Ta, Ru, W, Mo, Pt, Ni, Co, TiN, TaN, WN, NbN, TiAl, TiAlN, TiSi, TiSiN, TaSiN, TaSiN, RuTiN, NiSi, CoSi, or combinations thereof, but the present inventive concept is not limited thereto. Each of the back gate lines BG may include a single layer or multiple layers, formed of the above-described materials.

The first structure ST1 may further include contact structures connected to the second source/drain regions SDc2. Each of the contact structures may include a plug portion 127 in contact with the active pattern ACTc, and a pad portion 125 on the plug portion 127.

Each of the information storage structures DS may include first electrodes 132 disposed on the pad portions 125, the first electrodes 132 extending (e.g., extending lengthwise) in the vertical direction (Z-direction), a second electrode 138 on a side surface and an upper surface of each of the first electrodes 132, and a dielectric layer 136 between the first electrodes 132 and the second electrode 138. Each of the information storage structures DS may form capacitors that store information in the form of a stored charge.

The first electrodes 132 may each be connected to a respective pad portion 125 of the contact structures. The first electrodes 132 may be electrically connected to a respective second source/drain region SDc2 through respective contact structures. Thus, each cell transistor cTR may be electrically connected to a respective information storage structure DS through the contact structures (e.g., pad portion 125 and plug portion 127).

Each of the information storage structures DS may form cell capacitors that store information as part of a memory such as a DRAM, but example embodiments are not limited thereto. For example, the information storage structures DS may be an information storage structure of an MRAM or an information storage structure of a FeRAM.

Each of the bit lines BL may be connected to active patterns ACTc of a corresponding group of active patterns ACTc below the active patterns ACTc. For example, a bit line BL may be electrically connected to the first source/drain regions SDc1 of a group of active patterns ACTc. Thus, the bit lines BL may be electrically connected to the cell transistors cTR.

The first structure ST1 may further include a shield conductive structure BS including line portions BSa alternately arranged with the bit lines BL, and a connection portion BSb connecting the line portions BSa to each other. The shield conductive structure BS may shield capacitive coupling between the bit lines BL. For example, the shield conductive structure BS may minimize RC (resistive-capacitive) delay of the bit lines BL by reducing or blocking parasitic capacitance between the bit lines BL.

The cell routing line structure CRL may be disposed on a lower portion of the cell transistors cTR. In an example, the cell routing line structure CRL may be disposed on a lower portion of the bit line BL. The cell routing line structure CRL may include a word line routing plug WLC connected to the word line WL, first cell routing lines, which may include (1-2)-th cell routing lines and a (1-1)-th cell routing line 167, connected to the word line routing plug WLC, a bit line routing plug BLC connected to the bit line BL, and second cell routing lines, which may include (2-2)-th cell routing lines and a (2-1)-th cell routing line 169 connected to the bit line routing plug BLC.

The (1-1)-th cell routing line 167 may be in contact with the word line routing plug WLC, and the (1-2)-th cell routing lines may connect the (1-1)-th cell routing line 167 and a cell bonding via 185 to each other. The (1-2)-th cell routing lines may include a plurality of pads 160W, and a plurality of vias 165W connecting the plurality of pads to each other.

The second cell routing lines may include a (2-1)-th cell routing line 169 in contact with the bit line routing plug BLC, and (2-2)-th cell routing lines connecting the (2-1)-th cell routing line 169 and the cell bonding via 185 to each other. The (2-2)-th cell routing lines may include a plurality of pads 160B and a plurality of vias 165B connecting the plurality of pads 160B to each other.

The first structure ST1 may further include first bonding structures. The first bonding structures may be disposed below the cell routing line structure CRL. The first bonding structures may include cell bonding pads 195 and cell bonding vias 185 connecting the cell bonding pads 195 and the cell routing line structure CRL to each other. In an example, the cell bonding vias 185 may connect the cell bonding pads 195 to the (1-2)-th cell routing lines and the (2-2)-th cell routing lines.

The cell bonding pads 195 may be connected to peripheral bonding pads 295 of the second structure ST2. The cell bonding pads 195 and the peripheral bonding pads 295 may provide an electrical connection path according to bonding between the first structure ST1 and the second structure ST2. In another example, a portion of the cell bonding pads 195 may not be connected to the cell routing line structure CRL, and may be disposed only for bonding.

The cell bonding pads 195, the peripheral bonding pads 295, the cell bonding vias 185, and peripheral bonding vias 285 may include a conductive material, for example, copper (Cu).

The first structure ST1 may further include a first cell bonding insulating layer 190 and a second cell bonding insulating layer 180. The first cell bonding insulating layer 190 may be disposed around the cell bonding pads 195. The first cell bonding insulating layer 190 may also function as a diffusion prevention layer of the cell bonding pads 195. The second cell bonding insulating layer 180 may be disposed around the cell bonding vias 185. The second cell bonding insulating layer 180 may also function as a diffusion prevention layer of the cell bonding vias 185. Each of the first cell bonding insulating layer 190 and the second cell bonding insulating layer 180 may include at least one of SiN, SiON, SiCN, SiOC, SiOCN, or SiO.

The bonding between the cell bonding pads 195 and the peripheral bonding pads 295 may be copper (Cu)-copper (Cu) bonding, and bonding between the first cell bonding insulating layer 190 and a first peripheral bonding insulating layer 290 may be, for example, dielectric-dielectric bonding such as SiCN—SiCN bonding. The first structure ST1 and the second structure ST2 may be bonded to each other using hybrid bonding including copper (Cu)-copper (Cu) bonding and dielectric-dielectric bonding.

The first structure ST1 may further include a cell hydrogen supply layer 101 on the second cell bonding insulating layer 180, a first cell insulating structure 104 on the cell hydrogen supply layer 101, a second cell insulating structure 105 on the first cell insulating structure 104, a first contact insulating layer 110 on the second cell insulating structure 105, a second contact insulating layer 120 on the first contact insulating layer 110, and an upper insulating structure 130 on the second contact insulating layer 120.

The cell hydrogen supply layer 101 may be in contact with the second cell bonding insulating layer 180, on the second cell bonding insulating layer 180, and may surround a portion of the cell routing line structure CRL. The cell hydrogen supply layer 101 may be disposed between the second cell bonding insulating layer 180 and the first cell insulating structure 104. A lower surface of the cell hydrogen supply layer 101 may be in contact with an upper surface of the second cell bonding insulating layer 180, and an upper surface of the cell hydrogen supply layer 101 may be in contact with a lower surface of the first cell insulating structure 104. In an example, the cell hydrogen supply layer 101 may surround the first cell routing lines (e.g., pads 160W, vias 165W, and first cell routing lines 167) and the second cell routing lines (e.g., pads 160B, vias 165B, and second cell routing lines 169). For example, the first cell routing lines and the second cell routing lines may be disposed in the cell hydrogen supply layer 101. However, the present inventive concept is not limited thereto, and the cell hydrogen supply layer 101 may surround a portion of the word line routing plug WLC connected to the (1-1)-th cell routing line 167, and a portion of the bit line routing plug BLC connected to the (2-1)-th cell routing line 169.

The cell hydrogen supply layer 101 may be a hydrogen-containing insulating layer containing hydrogen. The cell hydrogen supply layer 101 may include tetraethyl orthosilicate (TEOS) oxide. However, the present inventive concept is not limited thereto, and the cell hydrogen supply layer 101 may include, for example, boro-phosphosilicate glass (BPSG), tonn sazene (TOSZ), undoped silicate glass (USG), spin-on glass (SOG), flowable oxide (FOX), a high-density plasma CVD (HDP CVD) insulating material, or hydrogen silsesquioxane (HSQ).

Hydrogen H in the cell hydrogen supply layer 101 may be connected to the word line WL through the first cell routing lines and the word line routing plug WLC, and may be diffused to surfaces of the active patterns ACTc (e.g., hydrogen may diffuse through the cell routing lines to the active patterns ACTc). The hydrogen H in the cell hydrogen supply layer 101 may be connected to the bit line BL through the second cell routing lines and the bit line routing plug BLC, and may be diffused to the surfaces of the active patterns ACTc. Trap sites of the active patterns ACTc may be filled with diffused hydrogens to reduce interfacial trap density. Accordingly, the cell transistor cTR may have improved leakage current properties.

The bit line BL and the shield conductive structure BS may be disposed in the first cell insulating structure 104. The first cell insulating structure 104 may surround a portion of the word line routing plug WLC and a portion of the bit line routing plug BLC. A structure, including the active patterns ACTc, the word lines WL, the back gate lines BG, the gate dielectric layers GOc1, and the back gate dielectric layers GOc2, may pass through the second cell insulating structure 105. The first contact insulating layer 110 may surround the plug portion 127. The second contact insulating layer 120 may surround the pad portions 125, on the first contact insulating layer 110. The upper insulating structure 130 may be disposed on the information storage structure DS and the second contact insulating layer 120. The first cell insulating structure 104, the second cell insulating structure 105, the first contact insulating layer 110, the second contact insulating layer 120, and the upper insulating structure 130 may include at least one of an insulating material, for example, silicon oxide, silicon nitride, or silicon carbide.

The cell hydrogen supply layer 101 may include a first insulating material including oxide. The first cell insulating structure 104, the second cell insulating structure 105, the first contact insulating layer 110, the second contact insulating layer 120, and the upper insulating structure 130 may include a second insulating material, different from the first insulating material.

In another example embodiment, the first cell insulating structure 104 may include a first insulating material the same as that of the cell hydrogen supply layer 101. In this case, an interface between the first cell insulating structure 104 and the cell hydrogen supply layer 101 may not be identified.

The first structure ST1 may further include a capacitor via 135 on the second electrode 138 of the information storage structure DS, a capacitor pad 145 on the capacitor via 135, a first upper interlayer insulating layer 140 surrounding the capacitor pad 145, a second upper interlayer insulating layer 143 on the first upper interlayer insulating layer 140, and external connection terminals (e.g., connection via 151 and connection pad 153) passing through the second upper interlayer insulating layer 143. The external connection terminals (e.g., connection via 151 and connection pad 153) may include a connection via 151 passing through the second upper interlayer insulating layer 143, and a connection pad 153 on the connection via 151. The external connection terminals (e.g., connection via 151 and connection pad 153) may transmit a signal, received externally, to the semiconductor device 100.

The second structure ST2 may further include a substrate 205 and an isolation region 209 for limiting active regions 207 on the substrate 205. The substrate 205 may be a semiconductor substrate. The second structure ST2 may further include a peripheral transistor PTR and a peripheral routing line structure PRL disposed on the semiconductor substrate 205. The peripheral transistor PTR may include a transistor of a sub word line driver and a transistor of a sense amplifier.

The peripheral transistor PTR may include peripheral gate structures GEp and GOp disposed on an active region 207, and peripheral source/drain regions SDp disposed in the active region 207 positioned on opposite sides of the peripheral gate structures GEp and GOp. The peripheral gate structures GEp and GOp may include a peripheral gate dielectric layer Gop and a peripheral gate electrode GEp, sequentially stacked.

The peripheral routing line structure PRL may include first peripheral connection structures and second peripheral connection structures connecting the first peripheral connection structures and the peripheral transistor PTR to each other. The first peripheral connection structures may include pads 260 disposed on different levels, and vias 265 connected to the pads 260. The second peripheral connection structures may include a via 269 connected to the peripheral source/drain regions SDp, and a pad 267 connected to the via 269.

The second structure ST2 may further include second bonding structures. The second bonding structures may be disposed on the peripheral routing line structure PRL. The second bonding structures may include a second bonding pad (e.g., peripheral bonding pad 295) and a peripheral bonding via 285 connecting the second bonding pad (e.g., peripheral bonding pad 295) and the peripheral routing line structure PRL to each other.

The second structure ST2 may further include a first peripheral bonding insulating layer 290 and a second peripheral bonding insulating layer 280. The first peripheral bonding insulating layer 290 may be disposed around the peripheral bonding pads 295. The first peripheral bonding insulating layer 290 may also function as a diffusion prevention layer of the peripheral bonding pads 295. The second peripheral bonding insulating layer 280 may be disposed around the peripheral bonding vias 285. The second peripheral bonding insulating layer 280 may also function as a diffusion prevention layer of the peripheral bonding vias 285. Each of the first peripheral bonding insulating layer 290 and the second peripheral bonding insulating layer 280 may include at least one of SiN, SiON, SiCN, SiOC, SiOCN, and SiO.

The second structure ST2 may further include a peripheral insulating structure 204 disposed between the second peripheral bonding insulating layer 280 and the substrate 205. The peripheral insulating structure 204 may surround the peripheral routing line structure PRL. The peripheral insulating structure 204 may be in contact with a lower surface of the second peripheral bonding insulating layer 280 and an upper surface of the substrate 205. The peripheral insulating structure 204 may include an insulating material, and may include at least one of an insulating material, for example, silicon oxide, silicon nitride, or silicon carbide.

In another example embodiment, the peripheral insulating structure 204 may function as a peripheral hydrogen supply layer. The peripheral insulating structure 204 may be a hydrogen-containing insulating structure containing hydrogen, and hydrogen in the peripheral insulating structure 204 may be diffused into the peripheral transistor PTR.

A semiconductor device according to example embodiments of the present inventive concept may include a cell hydrogen supply layer 101 spaced apart from the information storage structure DS with the cell transistor cTR interposed therebetween, the cell hydrogen supply layer 101 surrounding at least a portion of the cell routing line structure CRL, thereby minimizing and/or improving the effect on the information storage structure DS caused by an arrangement of the cell hydrogen supply layer 101. As a result, the information storage structure DS may have improved electrical properties and reliability.

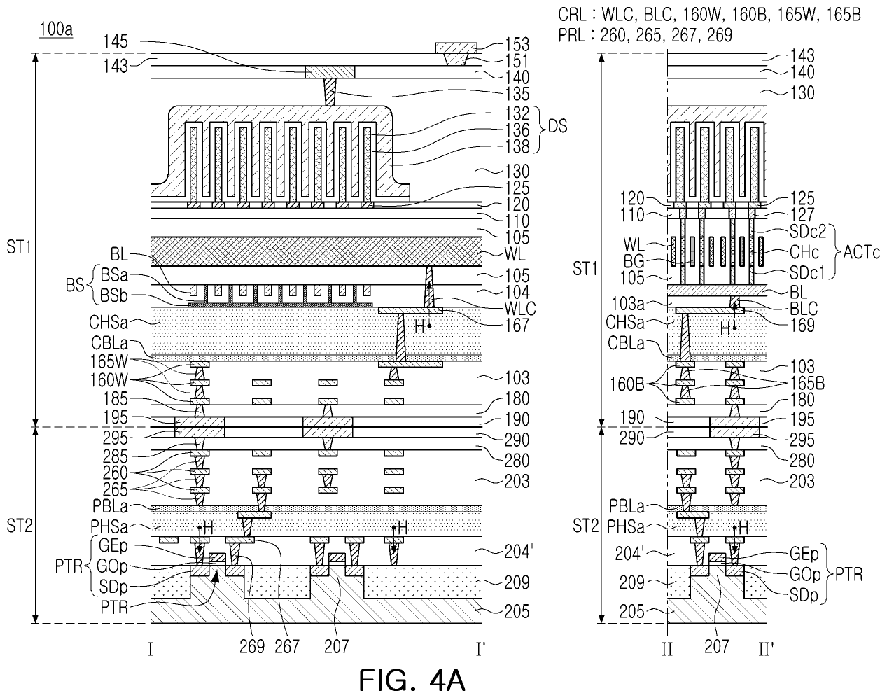

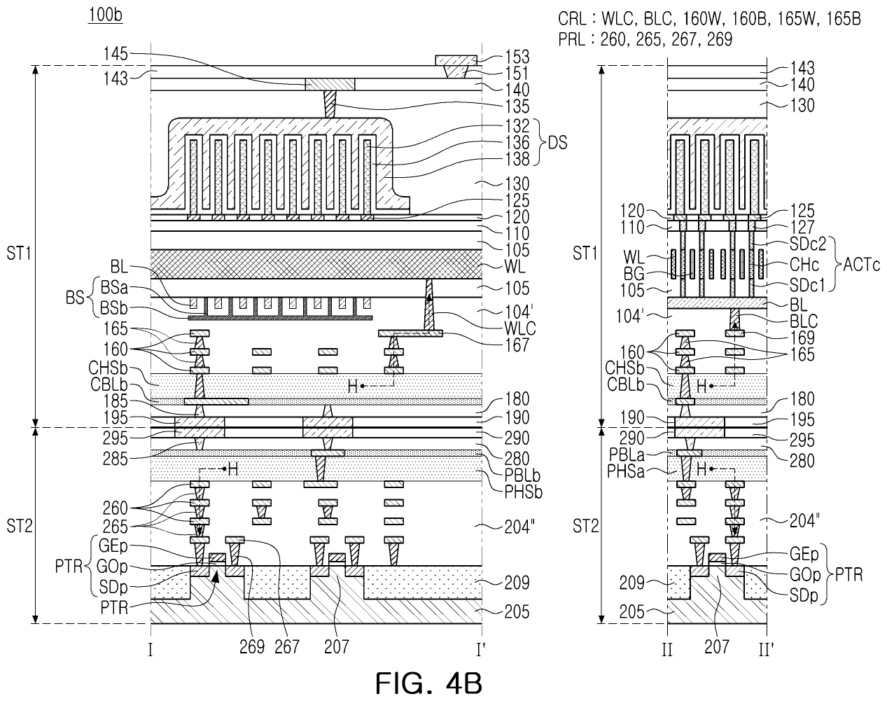

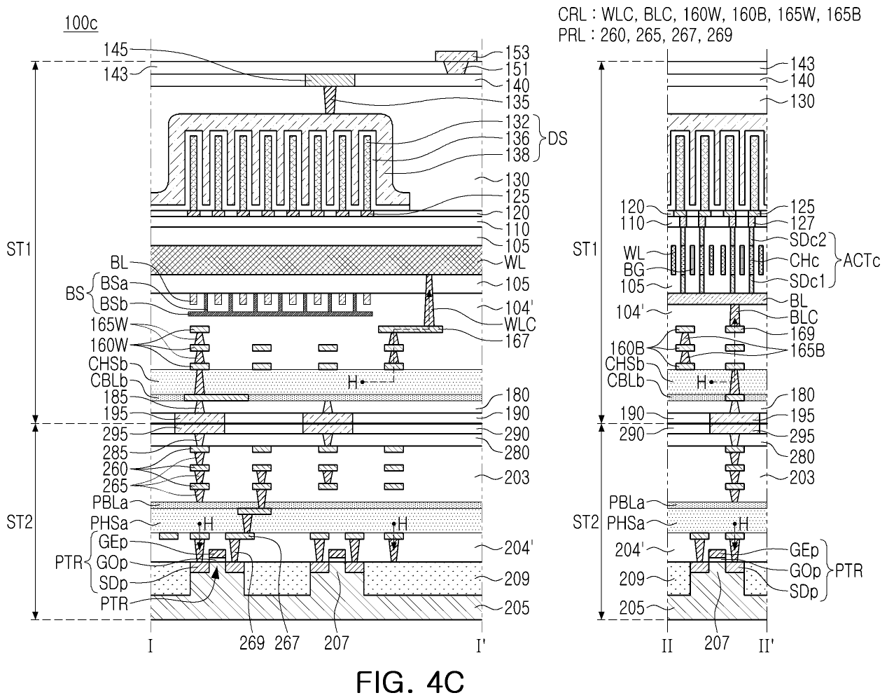

FIGS. 4A to 4C are cross-sectional views of a semiconductor device as illustrated in FIG. 2 according to another example embodiment, taken along line I-I′ and line II-II′. FIGS. 4A to 4C are cross-sectional views of semiconductor devices having a Cell on Peri (CoP) structure in which a first structure ST1 is disposed on a second structure ST2.

Referring to FIG. 4A, a semiconductor device 100a may be the same as or correspond to the semiconductor device 100 illustrated in FIG. 3 in terms of components, except for a first cell hydrogen supply layer CHSa in a first structure ST1, a first cell blocking layer CBLa disposed on one surface of the first cell hydrogen supply layer CHSa, a first peripheral hydrogen supply layer PHSa in a second structure ST2, and a first peripheral blocking layer PBLa disposed on one surface of the first peripheral hydrogen supply layer PHSa. Among components excluding the first cell hydrogen supply layer CHSa, the first cell blocking layer CBLa, the first peripheral hydrogen supply layer PHSa, and the first peripheral blocking layer PBLa, descriptions of components that are the same as or corresponding to those illustrated in FIG. 3 may be omitted.

The semiconductor device 100a may further include a cell lower insulating structure 103 of the first structure ST1, a peripheral upper insulating structure 203 of the second structure ST2 and a peripheral insulating structure 204′ (e.g., a lower interlayer insulating layer) of the second structure ST2.

The cell lower insulating structure 103 may be disposed on the second cell bonding insulating layer 180, and may surround a portion of the cell routing line structure CRL. The cell lower insulating structure 103 may surround a portion of (1-2)-th cell routing lines and a portion of (2-2)-th cell routing lines, connected to cell bonding vias 185.

The first cell hydrogen supply layer CHSa and the first cell blocking layer CBLa, disposed on the one surface of the first cell hydrogen supply layer CHSa, may be disposed between a first cell insulating structure 104 and a cell lower insulating structure 103. The first cell hydrogen supply layer CHSa may be disposed on the cell lower insulating structure 103. The first cell hydrogen supply layer CHSa may have a first surface adjacent to the bit line BL, and a second surface opposing the first surface. The first cell blocking layer CBLa may be disposed on the second surface of the first cell hydrogen supply layer CHSa.

The first cell hydrogen supply layer CHSa may surround a portion of a word line routing plug WLC, a (1-1)-th cell routing line 167 connected to the word line routing plug WLC, a portion of a bit line routing plug BLC, and a (2-1)-th cell routing line 169 connected to the bit line routing plug BLC. However, the present inventive concept is not limited thereto, and the word line routing plug WLC and the bit line routing plug BLC may be surrounded by the first cell insulating structure 104.

The first cell hydrogen supply layer CHSa may include an insulating material having relatively high hydrogen supply capacity. For example, the first cell hydrogen supply layer CHSa may include a first insulating material. For example, the first insulating material may include tetraethyl orthosilicate (TEOS) oxide, boro-phosphosilicate glass (BPSG), tonn sazene (TOSZ), undoped silicate glass (USG), spin-on glass (SOG), flowable oxide (FOX), a HDP CVD insulating material, or hydrogen silsesquioxane (HSQ).

The first cell insulating structure 104 and the cell lower insulating structure 103 may include a second insulating material, different from the first insulating material. For example, the second insulating material may include at least one of silicon oxide, silicon nitride, or silicon carbide.

The first cell blocking layer CBLa may prevent a hydrogen H in the first cell hydrogen supply layer CHSa from being diffused into the cell lower insulating structure 103, and may be diffused to the bit line BL. The first cell blocking layer CBLa may include a nitride film. For example, the first cell blocking layer CBLa may include SiN.

The first cell blocking layer CBLa may be in contact with an upper surface of the cell lower insulating structure 103, and may be in contact with a lower surface of the first cell hydrogen supply layer CHSa. The lower surface of the first cell hydrogen supply layer CHSa may be in contact with an upper surface of the first cell blocking layer CBLa, and an upper surface of the first cell hydrogen supply layer CHSa may be in contact with a lower surface of the first cell insulating structure 104.

The second structure ST2 may include a first peripheral hydrogen supply layer PHSa disposed between the peripheral insulating structure 204′ and the peripheral upper insulating structure 203, and a first peripheral blocking layer PBLa on the first peripheral hydrogen supply layer PHSa.

The peripheral upper insulating structure 203 may be disposed on a lower surface of the second peripheral bonding insulating layer 280, and may surround a portion of the peripheral routing line structure PRL. The peripheral upper insulating structure 203 may surround a portion of the first peripheral connection structures.

The peripheral insulating structure 204′ may be disposed on a substrate 205 to surround the second peripheral connection structures connected to the peripheral source/drain regions SDp of a peripheral transistor PTR.

The first peripheral hydrogen supply layer PHSa may be disposed between an upper surface of the peripheral insulating structure 204′ and a lower surface of the peripheral upper insulating structure 203. A hydrogen H in the first peripheral hydrogen supply layer PHSa may be diffused to the peripheral transistor PTR through a portion of the peripheral routing line structure PRL in the first peripheral hydrogen supply layer PHSa and the second peripheral connection structures in the peripheral insulating structure 204′.

The first peripheral hydrogen supply layer PHSa may have a first surface adjacent to the peripheral transistor PTR, and a second surface opposing the first surface. The first peripheral blocking layer PBLa may be disposed on the second surface of the first peripheral hydrogen supply layer PHSa. The first peripheral blocking layer PBLa may prevent the hydrogen H in the first peripheral hydrogen supply layer PHSa from being diffused to the peripheral upper insulating structure 203.

A lower surface of the first peripheral hydrogen supply layer PHSa may be in contact with the upper surface of the peripheral insulating structure 204′, and an upper surface of the first peripheral hydrogen supply layer PHSa may be in contact with a lower surface of the first peripheral blocking layer PBLa. The lower surface of the first peripheral blocking layer PBLa may be in contact with the upper surface of the first peripheral hydrogen supply layer PHSa, and an upper surface of the first peripheral blocking layer PBLa may be in contact with the lower surface of the peripheral upper insulating structure 203.

The semiconductor device 100a according to the present example embodiments may include a first cell hydrogen supply layer CHSa and a first cell blocking layer CBLa spaced apart from the information storage structure DS with the cell transistor cTR interposed therebetween, such that a hydrogen H in the first cell hydrogen supply layer CHSa may be diffused to the cell transistor cTR, and an effect of an arrangement of the first cell hydrogen supply layer CHSa on the information storage structure DS may be minimized or improved.

Referring to FIG. 4B, a semiconductor device 100b may be the same as or correspond to the semiconductor device 100 illustrated in FIG. 3 in terms of components, except for a second cell hydrogen supply layer CHSb in a first structure ST1, a second cell blocking layer CBLb disposed on one surface of the second cell hydrogen supply layer CHSb, a second peripheral hydrogen supply layer PHSb in a second structure ST2, and a second peripheral blocking layer PBLb disposed on one surface of the second peripheral hydrogen supply layer PHSb. Among components excluding the second cell hydrogen supply layer CHSb, the second cell blocking layer CBLb, the second peripheral hydrogen supply layer PHSb, and the second peripheral blocking layer PBLb, descriptions of components that are the same as or corresponding to those illustrated in FIG. 3 may be omitted.

The semiconductor device 100b may further include a first cell insulating structure 104′ of the first structure ST1 and a peripheral insulating structure 204′ of the second structure ST2.

The second cell hydrogen supply layer CHSb and the second cell blocking layer CBLb disposed on the one surface of the second cell hydrogen supply layer CHSb may be disposed between a second cell bonding insulating layer 180 and the first cell insulating structure 104′. The second cell hydrogen supply layer CHSb may have a first surface adjacent to a bit line BL, and a second surface opposing the first surface. The second cell blocking layer CBLb may be disposed on the second surface of the second cell hydrogen supply layer CHSb.

The second cell blocking layer CBLb may be disposed on the second cell bonding insulating layer 180. A lower surface of the second cell blocking layer CBLb may be in contact with an upper surface of the second cell bonding insulating layer 180. The second cell hydrogen supply layer CHSb may be disposed on an upper surface of the second cell blocking layer CBLb. The second cell hydrogen supply layer CHSb may surround a portion of (1-2)-th cell routing lines and a portion of (2-2)-th cell routing lines, connected to cell bonding vias 185.

The first cell insulating structure 104′ may be disposed on the second cell hydrogen supply layer CHSb, and an upper surface of the second cell hydrogen supply layer CHSb may be in contact with a lower surface of the first cell insulating structure 104′.

The first cell insulating structure 104′ may surround the bit line BL, a shield conductive structure BS, a portion of a word line routing plug WLC, a (1-1)-th cell routing line 167 connected to the word line routing plug WLC, a bit line routing plug BLC, and a (2-1)-th cell routing line 169 connected to the bit line routing plug BLC.

A hydrogen H in the second cell hydrogen supply layer CHSb may be diffused to a word line routing plug WLC and a bit line routing plug BLC in the first cell insulating structure 104′ through a portion of the (1-2)-th cell routing lines 160W and 165W and a portion of the (2-2)-th cell routing lines 160B and 165B.

The second cell hydrogen supply layer CHSb may include an insulating material having relatively high hydrogen supply capacity. The second cell hydrogen supply layer CHSb may include a first insulating material, and the first cell insulating structure 104′ may include a second insulating material, different from the first insulating material.

The second structure ST2 may include a second peripheral hydrogen supply layer PHSb disposed between a second peripheral bonding insulating layer 280 and the peripheral insulating structure 204′, and a second peripheral blocking layer PBLb on the second peripheral hydrogen supply layer PHSb.

The second peripheral hydrogen supply layer PHSb may have a first surface adjacent to a peripheral transistor PTR, and a second surface opposing the first surface. The second peripheral blocking layer PBLb may be disposed on the second surface of the second peripheral hydrogen supply layer PHSb. In an example, the second peripheral blocking layer PBLb may be disposed on a lower surface of the second peripheral bonding insulating layer 280. An upper surface of the second peripheral blocking layer PBLb may be in contact with the lower surface of the second peripheral bonding insulating layer 280. An upper surface of the second peripheral hydrogen supply layer PHSb may be in contact with a lower surface of the second peripheral blocking layer PBLb, and a lower surface of the second peripheral hydrogen supply layer PHSb may be in contact with an upper surface of a peripheral insulating structure 204″. The second peripheral hydrogen supply layer PHSb may surround a portion of a peripheral routing line structure PRL connected to peripheral bonding vias 285.

The peripheral insulating structure 204″ may be disposed between a substrate 205 and the second peripheral hydrogen supply layer PHSb to surround a portion of second peripheral connection structures and a portion of second peripheral connection structures, connected to peripheral source/drain regions SDp.

A hydrogen H in the second peripheral hydrogen supply layer PHSb may be diffused to the second peripheral connection structures in the peripheral insulating structure 204″ through a portion of the peripheral routing line structure PRL, and may be transferred to the peripheral transistor PTR.

Referring to FIG. 4C, a semiconductor device 100c may be the same as or correspond to the semiconductor device 100 illustrated in FIG. 3 in terms of components, except for a second cell hydrogen supply layer CHSb in a first structure ST1, a second cell blocking layer CBLb disposed on one surface of the second cell hydrogen supply layer CHSb, a first peripheral hydrogen supply layer PHSa in a second structure ST2, and a first peripheral blocking layer PBLa disposed on one surface of the first peripheral hydrogen supply layer PHSa. Among components excluding the second cell hydrogen supply layer CHSb, the second cell blocking layer CBLb, the first peripheral hydrogen supply layer PHSa, and the first peripheral blocking layer PBLa, descriptions of components that are the same as or corresponding to those illustrated in FIG. 3 may be omitted.

The semiconductor device 100c may further include a first cell insulating structure 104′ of the first structure ST1, and a peripheral upper insulating structure 203 and a peripheral insulating structure 204′ of the second structure ST2.

The second cell hydrogen supply layer CHSb and the second cell blocking layer CBLb of the semiconductor device 100c may correspond to the second cell hydrogen supply layer CHSb and the second cell blocking layer CBLb of the semiconductor device 100b of FIG. 4B. The first peripheral hydrogen supply layer PHSa and the first peripheral blocking layer PBLa of the semiconductor device 100c may correspond to the first peripheral hydrogen supply layer PHSa and the first peripheral blocking layer PBLa of the semiconductor device 100a of FIG. 4A.

In another example embodiment, a semiconductor device may include a first structure ST1 including the first cell hydrogen supply layer CHSa and the first cell blocking layer CBLa of FIG. 4A, and a second structure ST2 including the second peripheral hydrogen supply layer PHSb and the second peripheral blocking layer PHLb of FIG. 4B.

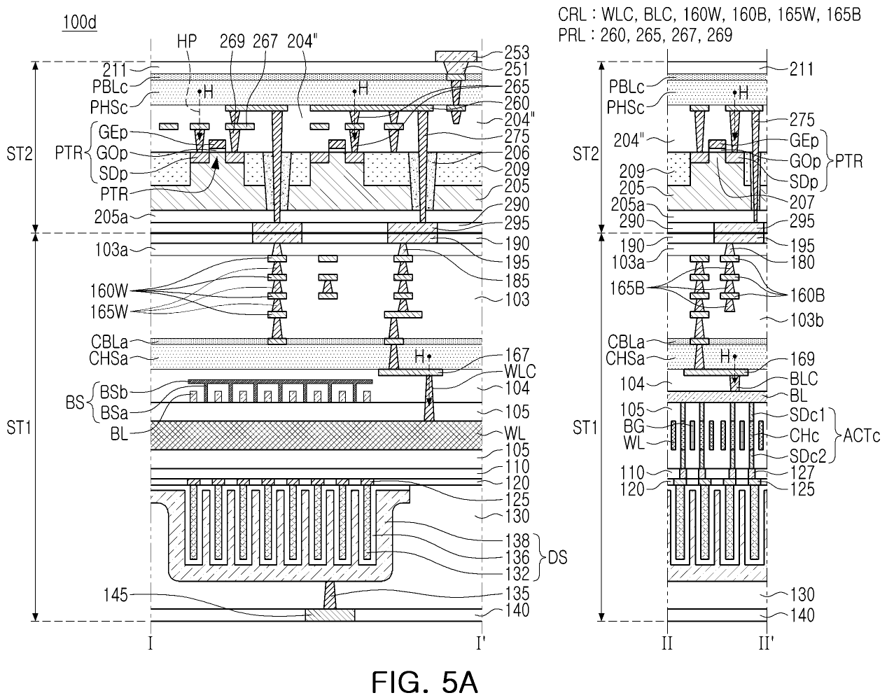

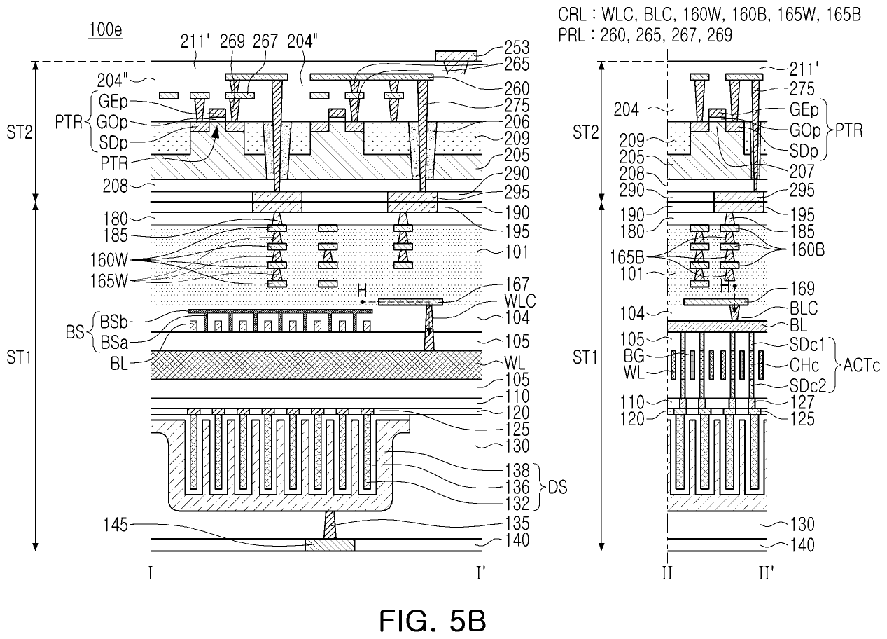

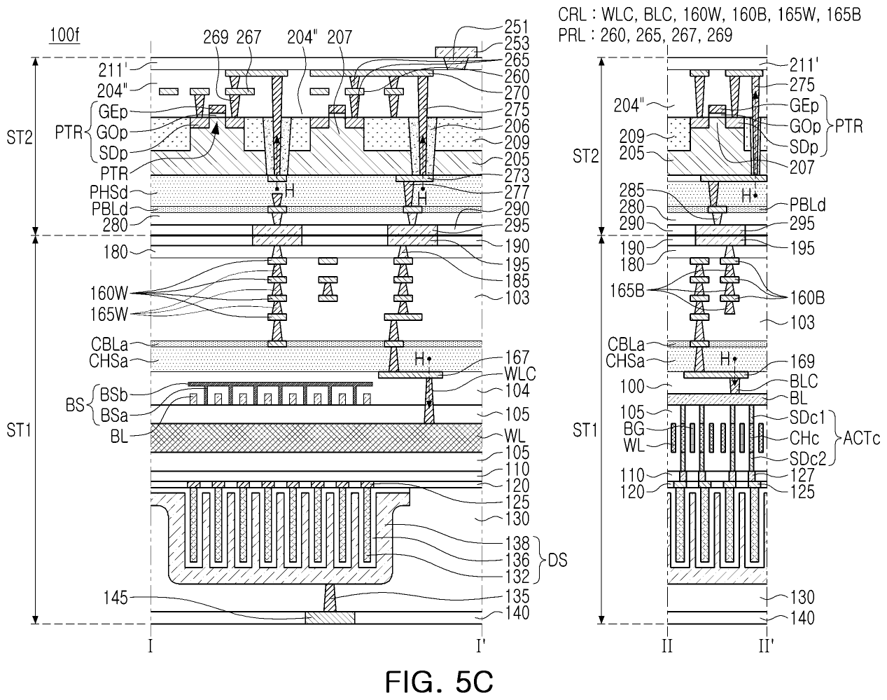

FIGS. 5A to 5C are cross-sectional views of a semiconductor device as illustrated in FIG. 2 according to another example embodiment, taken along line I-I′ and line II-II′. FIGS. 5A to 5C are cross-sectional views of semiconductor devices having a Peri on Cell (PoC) structure in which a second structure ST2 is disposed on a first structure ST1.

Referring to FIG. 5A, a semiconductor device 100d may include a first structure ST1 and a second structure ST2 bonded to an upper surface of the first structure ST1. The first structure ST1 of the semiconductor device 100d may include an information storage structure DS, a word line WL disposed on a level higher than that of the information storage structure DS, a bit line BL, an active pattern ACTc, a cell routing line structure CRL disposed on a level higher than that of the active pattern ACTc, a cell lower insulating structure 103 disposed on a lower surface of the second cell bonding insulating layer 180, the cell lower insulating structure 103 surrounding a portion of the cell routing line structure CRL, and first bonding structures on the cell lower insulating structure 103. The second structure ST2 of the semiconductor device 100d may include a peripheral transistor PTR, a peripheral routing line structure PRL on the peripheral transistor PTR, a peripheral insulating structure 204″ surrounding a portion of the peripheral routing line structure PRL, and second bonding pads (e.g., peripheral bonding pad 295) disposed on a level lower than that of a substrate 205 on the peripheral insulating structure 204″.

The first structure ST1 of the semiconductor device 100d may further include a first cell hydrogen supply layer CHSa and a first cell blocking layer CBLa disposed on an upper surface of the first hydrogen supply layer CHSa. The first cell hydrogen supply layer CHSa and the first cell blocking layer CBLa of the semiconductor device 100d may correspond to the first cell hydrogen supply layer CHSa and the first cell blocking layer CBLa of the semiconductor device 100a of FIG. 4A.

The second structure ST2 may further include a through-insulating pattern 206 passing through the substrate 205, and through-vias 275 passing through the through-insulating pattern 206. The through-vias 275 may pass through the through-insulating pattern 206, may extend upwardly (e.g., may extend lengthwise upwardly), and may be connected to second peripheral connection structures. The through-vias 275 may extend (e.g., extend lengthwise) to a lower portion of the through-insulating pattern 206, and may be connected to the second bonding pads (e.g., peripheral bonding pads 295). Each of the through-vias 275 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSiN, TaSiN, RuTiN, NiSi, CoSi, or combinations thereof, but the present inventive concept is not limited thereto. Each of the through-vias 275 may include a single layer or multiple layers, formed of the above-described materials.

The second structure ST2 may further include a backside insulating layer 205a covering a lower surface of the substrate 205 and a lower surface of the through-insulating pattern 206. A first peripheral bonding insulating layer 290, surrounding peripheral bonding pads 295, may be disposed on a lower surface of the backside insulating layer 205a.

The peripheral insulating structure 204″ may cover an upper surface of the substrate 205, and may surround a portion of the peripheral routing line structure PRL. The peripheral insulating structure 204″ may surround second peripheral connection structures connected to peripheral source/drain regions SDp of the peripheral transistor PTR, first peripheral connection structures connected to the second peripheral connection structures, and through-vias 275 passing through the through-insulating pattern 206, the through-vias 275 extending (e.g., extending lengthwise) upwardly.

A third peripheral hydrogen supply layer PHSc may be disposed on the peripheral insulating structure 204″, and a third peripheral blocking layer PBLc may be disposed on one surface of the third peripheral hydrogen supply layer PHSc. The third peripheral hydrogen supply layer PHSc may be disposed on an upper surface of the peripheral insulating structure 204″. The peripheral hydrogen supply layer PHSc may have a first surface adjacent to the peripheral transistor PTR, and a second surface opposing the second surface. The third peripheral blocking layer PBLc may be disposed on the second surface of the third peripheral hydrogen supply layer PHSc. The third peripheral blocking layer PBLc may be in contact with an upper surface of the third peripheral hydrogen supply layer PHSc.

A hydrogen H in the third peripheral hydrogen supply layer PHSc may be diffused to the peripheral transistor PTR through the first peripheral connection structures in the peripheral insulating structure 204″ and the second peripheral connection structures connected to the first peripheral connection structures. The third peripheral blocking layer PBLc may prevent the hydrogen H in the third peripheral hydrogen supply layer PHSc from being diffused to an upper interlayer insulating layer 211 on the third peripheral blocking layer PBLc.

The third peripheral hydrogen supply layer PHSc may include an insulating material having relatively high hydrogen supply capacity. For example, the third peripheral hydrogen supply layer PHSc may include a first insulating material. The peripheral insulating structure 204″ and the upper interlayer insulating layer 211 may include a second insulating material, different from the first insulating material.

The upper interlayer insulating layer 211 may be disposed on the third peripheral blocking layer PBLc. The second structure ST2 may further include external connection terminals passing through the upper interlayer insulating layer 211. The external connection terminals may include a connection via 251 passing through the upper interlayer insulating layer 211 and a connection pad 253 on the connection via 251. The external connection terminals may transmit a signal, received externally, to the semiconductor device 100d.

Referring to FIG. 5B, a semiconductor device 100e may be the same as or correspond to the semiconductor device 100d illustrated in FIG. 5A in terms of components, a cell hydrogen supply layer 101 on a lower surface of a second cell bonding insulating layer 180 of a first structure ST1 and an upper interlayer insulating layer 211′ on a peripheral insulating structure 204″ of a second structure ST2.

A cell hydrogen supply layer 101 in the first structure ST1 of the semiconductor device 100e may correspond to the cell hydrogen supply layer 101 in the first structure ST1 of the semiconductor device 100 of FIG. 2.

The upper interlayer insulating layer 211′ of the second structure ST2 may be in contact with an upper surface of the peripheral insulating structure 204″.

Referring to FIG. 5C, a semiconductor device 100f may include a first structure ST1 and a second structure ST2 bonded to an upper surface of the first structure ST1.

The first structure ST1 of the semiconductor device 100f may include an information storage structure DS, a word line WL disposed on a level higher than that of the information storage structure DS, a bit line BL, a cell active pattern ACTc, a cell routing line structure CRL disposed on a level higher than that of the cell active pattern ACTc, a cell lower insulating structure 103 disposed on a lower surface of a second cell bonding insulating layer 180, the cell lower insulating structure 103 surrounding a portion of the cell routing line structure CRL, and first bonding structures on the cell lower insulating structure 103.

The second structure ST2 of the semiconductor device 100f may include a peripheral transistor PTR, a peripheral routing line structure PRL on the peripheral transistor PTR, a peripheral insulating structure 204″ surrounding a portion of the peripheral routing line structure PRL, and second bonding structures disposed on a level lower than that of the peripheral transistor PTR.

The first structure ST1 of the semiconductor device 100f may further include a first cell hydrogen supply layer CHSa and a first cell blocking layer CBLa disposed on an upper surface of the first hydrogen supply layer CHSa. The first cell hydrogen supply layer CHSa and the first cell blocking layer CBLa of the semiconductor device 100f may correspond to the first cell hydrogen supply layer CHSa and the first cell blocking layer CBLa of the semiconductor device 100a of FIG. 4A.

The second structure ST2 of the semiconductor device 100f may further include a fourth peripheral hydrogen supply layer PHSd disposed between the second bonding structures and a substrate 205, and a fourth peripheral blocking layer PBLd disposed on one surface of the fourth peripheral hydrogen supply layer PHSd.

Through-vias 275 may pass through a through-insulating pattern 206, may extend (e.g., extend lengthwise) upwardly, and may be connected to first peripheral connection structures.

The through-vias 275 may pass through the through-insulating pattern 206, may extend (e.g., extend lengthwise) downwardly, and may be connected to third peripheral connection structures 273 and 277. The third peripheral connection structures 273 and 277 may be connected to peripheral bonding vias 285. The third peripheral connection structures 273 and 277 may be surrounded by the fourth peripheral hydrogen supply layer PHSd. The fourth peripheral hydrogen supply layer PHSd may be in contact with a lower surface of the substrate 205 and an upper surface of a second peripheral bonding insulating layer 280. The fourth peripheral hydrogen supply layer PHSd may have a first surface adjacent to the peripheral transistor PTR, and a second surface opposing the first surface. The fourth peripheral blocking layer PBLd may be disposed on the second surface of the fourth peripheral hydrogen supply layer PHSd.

A hydrogen H in the fourth peripheral hydrogen supply layer PHSd may be diffused to the peripheral transistor PTR through the third peripheral connection structures 273 and 277, the through-vias 275, the first peripheral connection structures, and second peripheral connection structures. The fourth peripheral blocking layer PBLd may minimize or improve diffusion of the hydrogen H in the fourth peripheral hydrogen supply layer PHSd to the peripheral bonding vias 285.

According to example embodiments of the present inventive concept, a semiconductor device may include a hydrogen supply layer supplying hydrogen to a vertical channel transistor, and the hydrogen supply layer may be disposed spaced apart from an information storage structure with a vertical channel transistor interposed therebetween, thereby minimizing or improving a leakage current phenomenon of the information storage structure due to the hydrogen supply layer. Accordingly, the semiconductor device may have improved electrical properties.

While example embodiments have been shown and described above, it will be apparent to those skilled in the art that modifications and variations could be made without departing from the scope of the present inventive concept.

What is claimed is:

1. A semiconductor device comprising:
a first semiconductor structure having a memory region; and
a second semiconductor structure on the first semiconductor structure and vertically overlapping the first semiconductor structure, the second semiconductor structure having a peripheral circuit region vertically overlapping the memory region,
wherein the first semiconductor structure includes:
a memory structure including a vertical channel transistor disposed in the memory region and an information storage structure disposed on the vertical channel transistor; and
a cell routing line structure electrically connected to the memory structure,
wherein the second semiconductor structure includes:
a peripheral circuit disposed in the peripheral circuit region; and
a peripheral routing line structure electrically connecting the peripheral circuit and the cell routing line structure to each other, and
the first semiconductor structure further includes a cell hydrogen supply layer disposed between the memory structure and the second semiconductor structure.

2. The semiconductor device of claim 1, wherein the vertical channel transistor is disposed between the information storage structure and the cell hydrogen supply layer.

3. The semiconductor device of claim 1, wherein
the vertical channel transistor includes:
a cell vertical active pattern;
a word line having a side surface facing a first side surface of the cell vertical active pattern;
a cell gate dielectric layer between the cell vertical active pattern and the word line; and
a bit line below the cell vertical active pattern, and
the cell routing line structure includes a word line routing plug connected to the word line, first cell routing lines connected to the word line routing plug, a bit line routing plug connected to the bit line, and second cell routing lines connected to the bit line routing plug.

4. The semiconductor device of claim 3, wherein the cell hydrogen supply layer surrounds the first cell routing lines and the second cell routing lines.

5. The semiconductor device of claim 3, wherein
the first semiconductor structure further includes a cell bonding pad and a cell bonding via connecting the cell bonding pad and the cell routing line structure to each other, and
the second semiconductor structure further includes a peripheral bonding pad disposed on the peripheral routing line structure, the peripheral bonding pad bonded to the cell bonding pad, and a peripheral bonding via connecting the peripheral bonding pad and the peripheral routing line structure to each other.

6. The semiconductor device of claim 5, wherein
the first cell routing lines include a (1-1)-th cell routing line in contact with the word line routing plug, and (1-2)-th cell routing lines connecting the (1-1)-th cell routing line and the cell bonding via to each other, and
the second cell routing lines include a (2-1)-th cell routing line in contact with the bit line routing plug, and (2-2)-th cell routing lines connecting the (2-1)-th cell routing line and the cell bonding via to each other.

7. The semiconductor device of claim 6, wherein
the cell hydrogen supply layer surrounds the (1-1)-th cell routing line and the (2-1)-th cell routing line, and
the first semiconductor structure further includes a cell lower insulating structure surrounding a portion of the (1-2)-th cell routing lines and a portion of the (2-2)-th cell routing lines below the cell hydrogen supply layer.

8. The semiconductor device of claim 6, wherein
the cell hydrogen supply layer surrounds the (1-2)-th cell routing lines and the (2-2)-th cell routing lines, and
the first semiconductor structure further includes a cell upper insulating layer, surrounding the (1-1)-th cell routing line and the (2-1)-th cell routing line above the cell hydrogen supply layer.

9. The semiconductor device of claim 5, wherein the second semiconductor structure further includes a peripheral hydrogen supply layer disposed between the peripheral circuit and the peripheral bonding via.

10. The semiconductor device of claim 9, wherein the peripheral routing line structure includes (1-1)-th peripheral routing lines connected to the peripheral bonding via, and (1-2)-th peripheral routing lines connecting the (1-1)-th peripheral routing line and the peripheral circuit to each other.

11. The semiconductor device of claim 10, wherein
the peripheral hydrogen supply layer surrounds the (1-2)-th peripheral routing lines, and
the second semiconductor structure further includes a peripheral upper insulating structure surrounding the (1-1)-th peripheral routing lines.

12. The semiconductor device of claim 5, wherein the cell hydrogen supply layer is in contact with the cell bonding via.

13. The semiconductor device of claim 5, wherein
the peripheral circuit has a first surface adjacent to the peripheral bonding pad, and a second surface opposing the first surface,
the peripheral routing line structure is disposed on the second surface of the peripheral circuit, and
the second semiconductor structure further includes a peripheral hydrogen supply layer disposed on the peripheral routing line structure.

14. The semiconductor device of claim 1, wherein
the cell hydrogen supply layer has a first surface adjacent to the vertical channel transistor, and a second surface opposing the first surface, and
the first semiconductor structure further includes a cell insulating blocking layer in contact with the second surface of the cell hydrogen supply layer.

15. A semiconductor device comprising:
a first semiconductor structure having a memory region; and
a second semiconductor structure, in contact with the first semiconductor structure, the second semiconductor structure having a peripheral circuit region vertically overlapping the memory region,
wherein the first semiconductor structure includes:
a memory structure including a vertical channel transistor disposed in the memory region, and an information storage structure disposed on the vertical channel transistor;
a cell routing line structure disposed below the vertical channel transistor, the cell routing line structure electrically connected to the memory structure;
a cell bonding structure disposed below the cell routing line structure;
a cell hydrogen supply layer, surrounding a portion of the cell routing line structure, between the cell bonding structure and the vertical channel transistor, the cell hydrogen supply layer including a first insulating material; and
a cell insulating layer, surrounding at least a portion of the vertical channel transistor, on the cell hydrogen supply layer, the cell insulating layer including a second insulating material, different from the first insulating material, and
wherein the second semiconductor structure includes:
peripheral circuits disposed in the peripheral circuit region;
a peripheral routing line structure electrically connecting the peripheral circuits and the cell routing line structure to each other; and
a peripheral bonding structure disposed on the peripheral routing line structure, the peripheral bonding structure in contact with the cell bonding structure.

16. The semiconductor device of claim 15, wherein the cell hydrogen supply layer is in contact with an upper surface of the cell bonding structure.

17. The semiconductor device of claim 16, wherein
the cell routing line structure includes:
a word line routing plug connected to a word line of the vertical channel transistor;
first cell routing lines connected to the word line routing plug;
a bit line routing plug connected to a bit line of the vertical channel transistor; and
second cell routing lines connected to the bit line routing plug, the first cell routing lines and the second cell routing lines are surrounded by the cell hydrogen supply layer, and
a portion of the word line routing plug and a portion of the bit line routing plug are surrounded by the cell insulating layer.

18. The semiconductor device of claim 15, wherein the cell hydrogen supply layer includes tetraethyl orthosilicate (TEOS) oxide.

19. A semiconductor device comprising:
a first semiconductor structure having a memory region; and
a second semiconductor structure, in contact with the first semiconductor structure, the second semiconductor structure vertically overlapping the first semiconductor structure, the second semiconductor structure having a peripheral circuit region vertically overlapping the memory region,
wherein the first semiconductor structure includes:
a memory structure including a vertical channel transistor disposed in the memory region, and an information storage structure disposed on the vertical channel transistor; and
a cell routing line structure electrically connected to the memory structure,
wherein the second semiconductor structure includes:
a peripheral circuit disposed in the peripheral circuit region; and
a peripheral routing line structure electrically connecting the peripheral circuit and the cell routing line structure to each other,
the first semiconductor structure further includes a cell hydrogen supply layer, surrounding a portion of the cell routing line structure, between the vertical channel transistor and the second semiconductor structure, and
the second semiconductor structure further includes a peripheral hydrogen supply layer surrounding a portion of the peripheral routing line structure.

20. The semiconductor device of claim 19, wherein
the cell hydrogen supply layer and the peripheral hydrogen supply layer include a first insulating material,
the first semiconductor structure further includes a cell insulating layer, surrounding at least a portion of the vertical channel transistor, on the cell hydrogen supply layer, the cell insulating layer including a second insulating material, different from the first insulating material,
the second semiconductor structure further includes a peripheral insulating layer, surrounding a portion of the peripheral routing line structure, between the peripheral circuit and the peripheral hydrogen supply layer, the peripheral insulating layer including the second insulating material.
